(19) United States
(12) Patent Application Publication
(10) Pub. No.: US 2015/0075847 A1
(43) Pub. Date: Mar. 19, 2015

(54) METAL-ELECTRODEPOSITED INSULATOR SUBSTRATE AND METHOD OF MAKING THE SAME

(71) Applicant: Taiwan Green Point Enterprises Co., Ltd., Taichung City (TW)

(72) Inventors: Pen-Yi Liao, Taichung City (TW); Tsung-Han Wu, Taichung City (TW); Yao-Tsung Ho, Taichung City (TW); Po-Cheng Huang, Taichung City (TW); Fang-Ju Lin, Taichung City (TW); Cheng-Yi Lin, Taichung City (TW)

(21) Appl. No.: 14/487,467

(22) Filed: Sep. 16, 2014

(30) Foreign Application Priority Data
Sep. 16, 2013 (TW) 102133470

(51) Int. Cl. H05K 3/18; H05K 1/02; C25D 5/34; C25D 7/12; C25D 5/02

(52) U.S. Cl. CPC H05K 3/18; C25D 7/123; C25D 5/02; C25D 5/34; H05K 1/0296; H05K 2203/07
USPC 174/255; 205/126; 174/250

(57) ABSTRACT

A method of making a metal-electrodeposited insulator substrate includes: forming first and second continuous conductor parts of a patterned conductive base layer on a pattern-forming surface of an insulator substrate; subjecting an assembly of the patterned conductive base layer and the insulator substrate to electroplating so as to simultaneously form first and second electroplating parts of a patterned electroplating layer on the patterned conductive base layer; and removing a sacrificial portion of the first continuous conductor part and a sacrificial portion of the first electroplating part from the insulator substrate.

### CROSS-REFERENCE TO RELATED APPLICATION

This application claims priority of Taiwanese Application No. 102133470, filed on Sep. 16, 2013.

### FIELD OF THE INVENTION

This invention relates to a metal-electrodeposited insulator substrate and a method of making the same, such as a method of making a metal-electrodeposited insulator substrate that includes forming sacrificial portions of a conductor stack.

### DESCRIPTION OF THE RELATED ART

Housings of electronic devices may be formed with electrodeposited metal elements at different regions for purposes, such as to form circuits, decoration, protection elements, all by way of non-limiting example. The housings may be formed of an insulator material, such as a polymer resin, glass, a ceramic material or a composite material. Simultaneous formation of the electrodeposited metal elements on different regions of an insulator housing may be conducted using electroplating techniques. However, when the regions to be electrodeposited have different areas, the electrodeposited metal element formed on the region having a larger area may have a thickness larger than that of the electrodeposited metal element formed on the region having a smaller area. The difference between the thicknesses of the electrodeposited metal elements formed on the regions may be undesirably large when the difference between the areas of the regions is large.

### SUMMARY OF THE INVENTION

According to certain embodiments of the invention, there may be provided a metal-electrodeposited insulator substrate and a method of making the same that can overcome the aforesaid drawback associated with the prior art.

According to one embodiment of this invention, there may be provided a method of making a metal-electrodeposited insulator substrate. Such a method may include: forming a patterned conductive base layer on a pattern-forming surface of an insulator substrate, such that the patterned conductive base layer has a first continuous conductor part and a second continuous conductor part that is spaced apart from the first continuous conductor part, each of the first and second continuous conductor parts having an electroplating surface, the first continuous conductor part having a target portion and at least one sacrificial portion that extends from the target portion; subjecting an assembly of the patterned conductive base layer and the insulator substrate to electroplating so as to simultaneously form first and second electroplating parts of a patterned electroplating layer on the patterned conductive base layer, such that the first electroplating part is formed on and overlaps entirely the electroplating surface of the first continuous conductor part, and that the second electroplating part is formed on and overlaps entirely the electroplating surface of the second continuous conductor part, the first electroplating part having at least one sacrificial portion that overlaps the sacrificial portion of the first continuous conductor part; and removing the sacrificial portion of the first continuous conductor part and the sacrificial portion of the first electroplating part from the insulator substrate.

According to another embodiment of the present invention, there may be provided a metal-electrodeposited insulator substrate that includes: an insulator substrate having a pattern-forming surface, the pattern-forming surface having first and second roughened regions and first and second non-roughened regions, the second non-roughened region extending from the first roughened region, the first non-roughened region surrounding the first and second roughened regions and the second non-roughened region and separating the first roughened region and the second non-roughened region apart from the second roughened region, each of the first and second roughened regions and the second non-roughened region having a peripheral edge, the pattern-forming surface being formed with first and second cut slits, the first cut slit surrounding and approximating the peripheral edges of the first roughened region and the second non-roughened region, the second cut slit surrounding and approximating the peripheral edge of the second roughened region, an entire area of the second roughened region being substantially equal to a total area of the first roughened region and the second non-roughened region; a first multi-layer conductor stack formed on and overlapping an entire area of the first roughened region and surrounded by the first cut slit; and a second multi-layer conductor stack formed on and overlapping an entire area of the second roughened region and surrounded by the second cut slit.

### BRIEF DESCRIPTION OF THE DRAWINGS

In drawings:

FIG. 1 is a schematic view to illustrate a preparation step of an embodiment of a method of making a metal-electrodeposited insulator substrate according to the present invention;

FIG. 2 is a schematic view to illustrate an active metal-containing layer-forming step of an embodiment according to the present invention;

FIG. 3 is a sectional view taken along line □-□ of FIG. 2;

FIG. 4 is a schematic view to illustrate an electroless plating seed layer-forming step according to an embodiment of the present invention;

FIG. 5 is a sectional view taken along line □-□ of FIG. 4;

FIG. 6 is a schematic view to illustrate a step of cutting a stack of the active metal-containing layer and the electroless plating seed layer according to an embodiment of the present invention;

FIG. 7 is a sectional view taken along line □-□ of FIG. 6;

FIG. 8 is a schematic view to illustrate a step of removing an excess conductor part from a first non-roughened region according to an embodiment of the present invention;

FIG. 9 is a sectional view taken along line □-□ of FIG. 8;

FIG. 10 is a schematic view to illustrate an electroplating step of forming first and second electroplating parts of a patterned electroplating layer according to an embodiment of the present invention; and

FIG. 11 is a sectional view taken along line XI-XI of FIG. 10.

### DETAILED DESCRIPTION

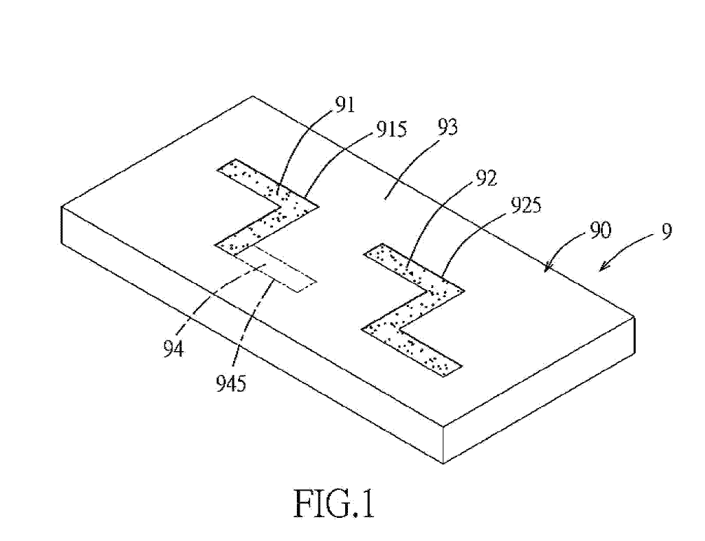

FIGS. 1 to 11 illustrate what may be consecutive steps of an embodiment of a method of making a metal- electrodeposited insulator substrate according to this invention. The metal-electrodeposited insulator substrate may be used for making a housing for an electronic product or a printed circuit board, for example.

The consecutive steps of a method according to an embodiment of the present invention are as follows.

First, an insulator substrate 9 are prepared (see FIG. 1). The insulator substrate 9 has a pattern-forming surface 90 that has first and second roughened regions 91, 92 and first and second non-roughened (or smooth) regions 93, 94. The second non-roughened region 94 extends from an end of the first roughened region 91. The first non-roughened region 93 surrounds the first and second roughened regions 91, 92 and the second non-roughened region 94. Each of the first and second roughened regions 91, 92 and the second non-roughened region 94 has a peripheral edge 915, 925, 945. An entire area of the second roughened region 92 is substantially equal to a total area of the first roughened region 91 and the second non-roughened region 94.

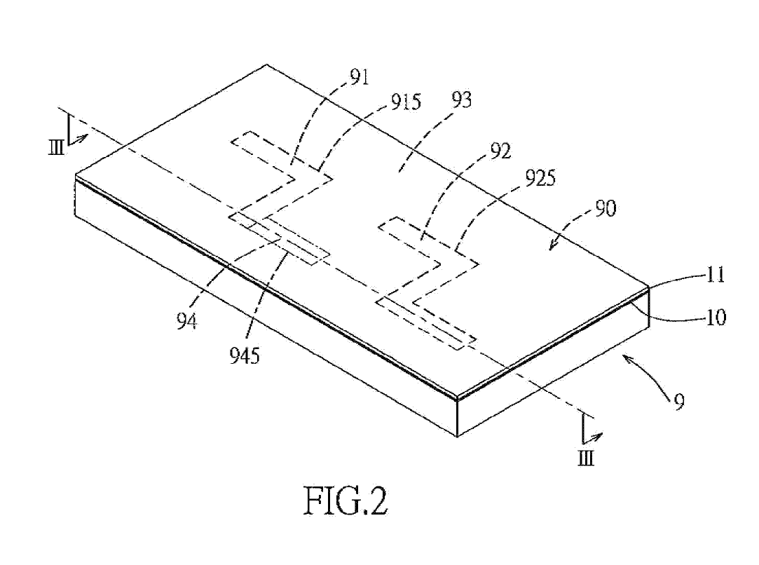

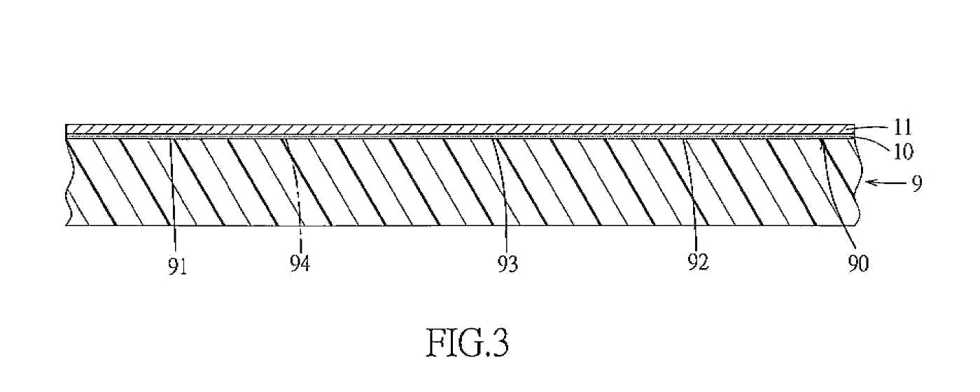

As shown in FIGS. 2 and 3, an active metal-containing layer 10 is formed on an entire area of the pattern-forming surface 90 of the insulator substrate 9, and an electroless plating seed layer 11 is formed on the active metal-containing layer 10.

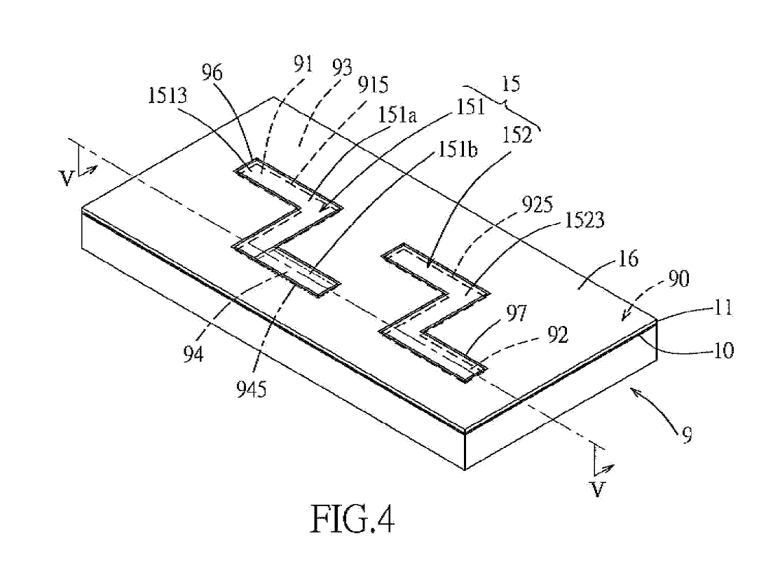

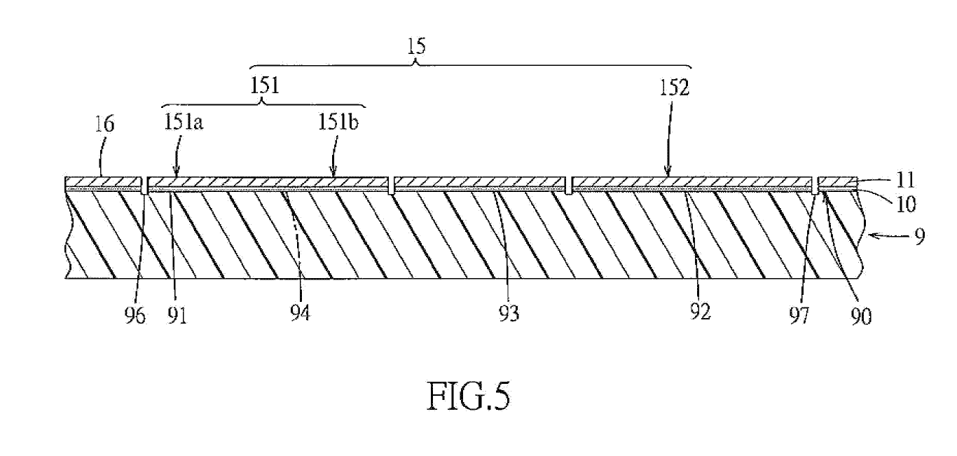

Then, a stack of the active metal-containing layer 10 and the electroless plating seed layer 11 are cut through into the insulator substrate 9 (see FIGS. 4 and 5) so as to form the stack into first and second continuous conductor parts 151, 152 and an excess conductor part 16 and so as to form first and second cut slits 96, 97 in the pattern-forming surface 90. The excess conductor part 16 is spaced apart from the first and second continuous conductor parts 151, 152 and separates the first and second continuous conductor parts 151, 152 apart from each other. The first and second continuous conductor parts 151, 152 cooperatively define a patterned conductive base layer 15. Each of the first and second continuous conductor parts 151, 152 has an electroplating surface 1513, 1523. An entire area of the electroplating surface 1513 of the first continuous conductor part 151 and an entire area of the electroplating surface 1523 of the second continuous conductor part 152 are substantially the same. The first continuous conductor part 151 has a target portion 151a and at least one sacrificial portion 151b that extends from the target portion 151a. The target portion 151a of the first continuous conductor part 151 is formed on and overlaps an entire area of the first roughened region 91 of the pattern-forming surface 90. The sacrificial portion 151b of the first continuous conductor part 151 is formed on and overlaps an entire area of the second non-roughened region 94. The second continuous conductor part 152 is formed on and overlaps an entire area of the second roughened region 92 of the pattern-forming surface 90. The excess conductor part 16 is formed on and overlaps the entire area of the first non-roughened region 93. The first cut slit 96 surrounds and approximates the peripheral edge 915 of the first roughened region 91 and the peripheral edge 945 of the second non-roughened region 94. The second cut slit 97 surrounds and approximates the peripheral edge 925 of the second roughened region 92.

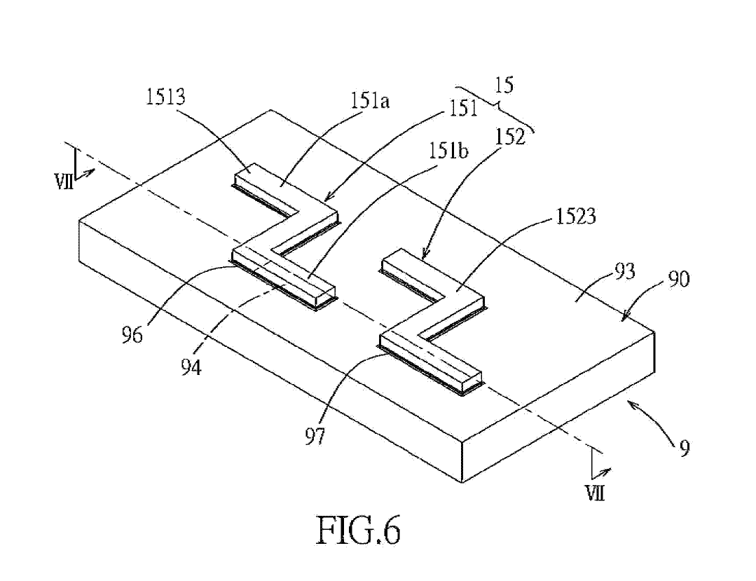

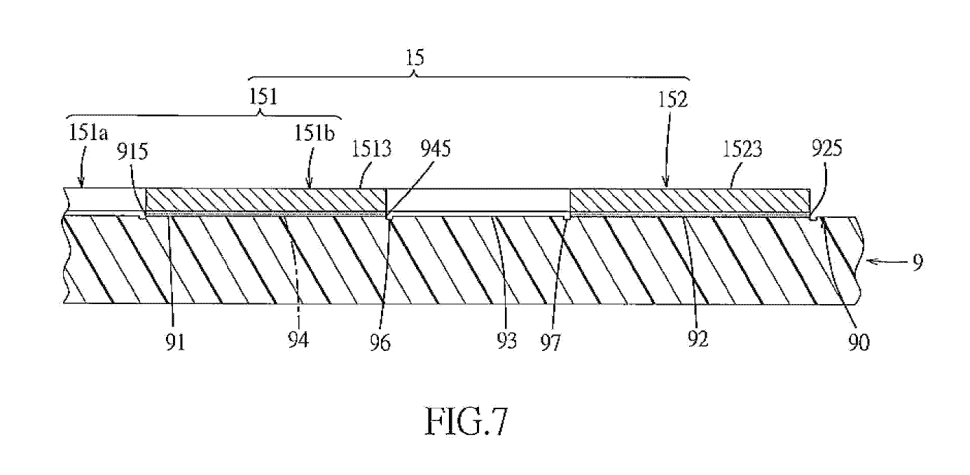

Thereafter, the excess conductor part 16 is removed from the first non-roughened region 93 of the pattern-forming surface 90 of the insulator substrate 9 (see FIGS. 6 and 7).

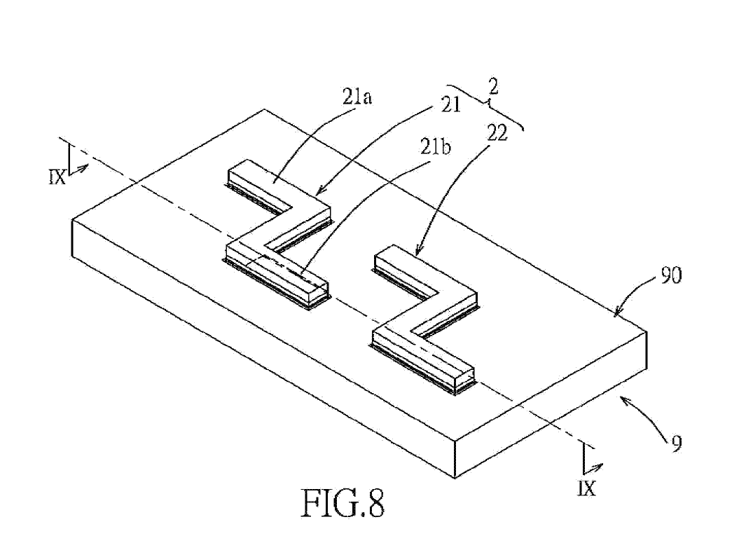

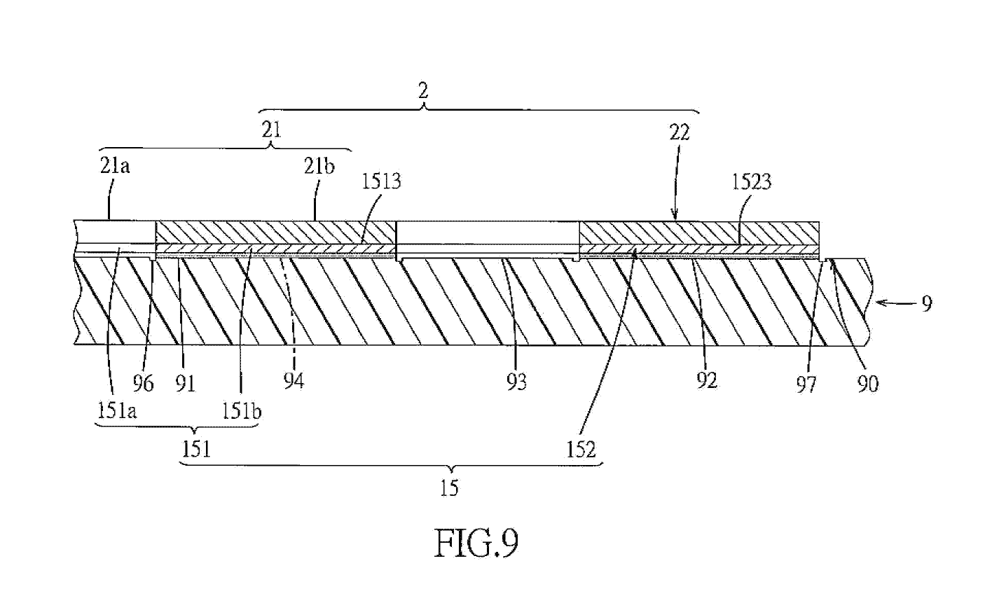

An assembly of the patterned conductive base layer 15 and the insulator substrate 9 are further subjected to electroplating (see FIGS. 8 and 9) so as to simultaneously form first and second electroplating parts 21, 22 of a patterned electroplating layer 2 on the patterned conductive base layer 15, such that the first electroplating part 21 is formed on and overlaps entirely the electroplating surface 1513 of the first continuous conductor part 151, and that the second electroplating part 22 is formed on and overlaps entirely the electroplating surface 1523 of the second continuous conductor part 152. The first electroplating part 21 has a target portion 21a that overlaps the target portion 151a of the first continuous conductor part 151, and at least one sacrificial portion 21b that overlaps the sacrificial portion 151b of the first continuous conductor part 151.

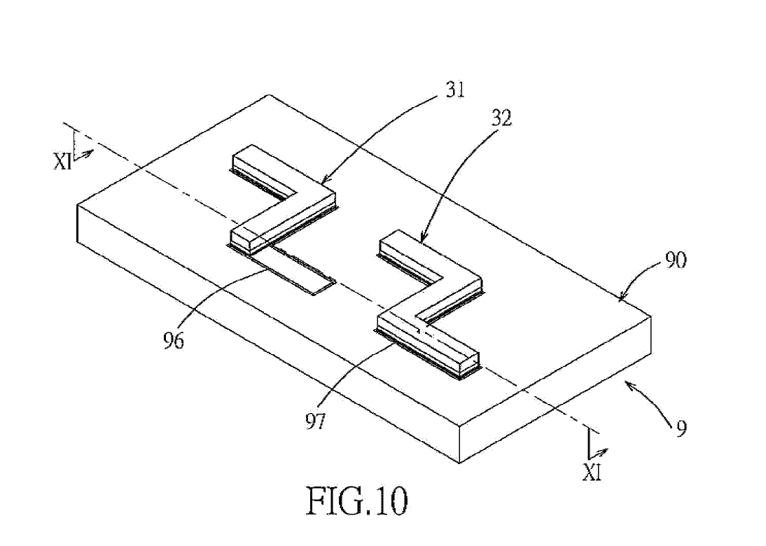

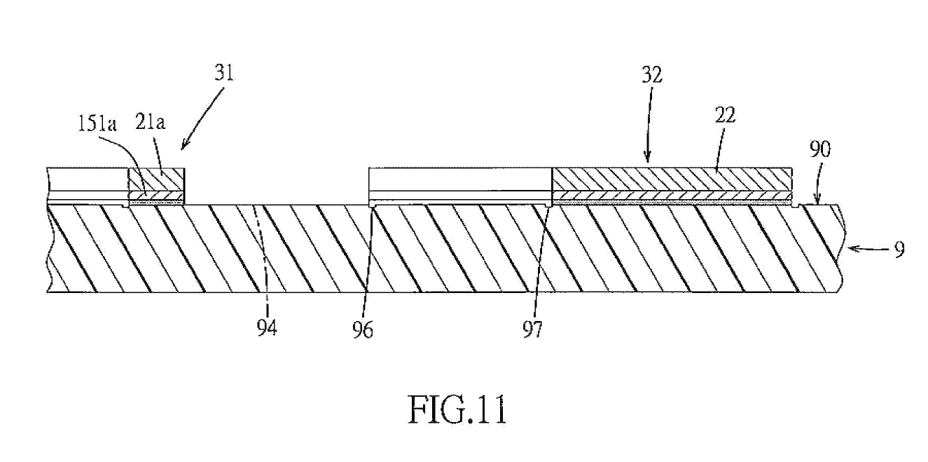

Thereafter, the sacrificial portion 151b of the first continuous conductor part 151 and the sacrificial portion 21b of the first electroplating part 21 are removed from the insulator substrate 9 (see FIGS. 10 and 11), thereby forming the metal-electrodeposited insulator substrate. The assembly of the target portion 151a of the first continuous conductor part 151 and the target portion 21a of the first electroplating part 21 cooperatively define a first multi-layer conductor stack 31. The assembly of the second continuous conductor part 152 and the second electroplating part 22 cooperatively define a second multi-layer conductor stack 32. Each of the first and second multi-layer conductor stacks 31, 32 has a stack thickness along a normal direction of the pattern-forming surface 90 of the insulator substrate 9. The stack thicknesses of the first and second multi-layer conductor stacks 31, 32 are substantially the same.

In certain embodiments of the present invention, the first and second roughened regions 91, 92 of the pattern-forming surface 90 of the insulator substrate 9 may be roughened using laser ablation techniques, for example.

The insulator substrate 9 maybe made from an insulative material. Suitable insulative material may include glass, ceramics, a polymer resin, and composites, for example.

Formation of the active metal-containing layer 10 on the pattern-forming surface 90 of the insulator substrate 9 may be conducted in a conventional manner, such as by immersing the insulator substrate 9 into an active metal-containing solution for a predetermined amount of time to allow attachment of active metal ions in the active metal-containing solution to the pattern-forming surface 90 of the insulator substrate 9, followed by reducing the attached active metal ions. The active metal ions contained in the active metal-containing solution may be any suitable metal, such as Pd, Pt, Rh, Ir, Os, Au, Ni, and Fe, all by way of non-limiting example.

Formation of the electroless plating seed layer 11 on the active metal-containing layer 10 may be conducted using any conventional manner.

Cutting of the active metal-containing layer 10, the electroless plating seed layer 11 and the insulator substrate 9 may be conducted by conventional cutting techniques, such as laser cutting or water jet cutting, both by way of non-limiting example. The cutting results in physical separation of the first and second continuous conductor parts 151, 152 and the excess conductor part 16, thereby facilitating subsequent removal of the excess conductor part 16 from the first non-roughened region 93.

Since the attachment strength of the excess conductor part 16 to the first non-roughened region 93 is much weaker as compared to that of the patterned conductive base layer 15 to the first and second roughened regions 91, 92, removal of the excess conductor part 16 from the first non-roughened region 93 may be conducted in a conventional manner by immersing an assembly of the insulator substrate 9 and the stack of the active metal-containing layer 10 and the electroless plating seed layer 11 into a chemical solution to chemically etch the active metal-containing layer 10 at the first non-roughened region 93. Conventional chemical etching techniques may be used.

In certain embodiments of the invention, the first and second cut slits 96, 97 may have a sufficient depth and width to physically isolate the first and second continuous conductor parts 151, 152 from one-another when the first multi-layer conductor stack 31 and the second multi-layer conductor stack 32 serve as contacts or electrical trace lines of a circuit and are disposed adjacent (or substantially adjacent) to each other.

With the inclusion of the sacrificial portion 151b in the first continuous conductor part 151 so that the electroplating surfaces 1513, 1523 of the first and second continuous conductor parts 151, 152 have substantially the same area for electroplating, the stack thicknesses of the first and second multi-layer conductor stacks 31, 32 thus formed maybe substantially the same.

While embodiments of the present invention have been described in connection with what is considered the most practical embodiment, it is understood that this invention is not limited to the disclosed embodiment but is intended to cover various arrangements included within the spirit and scope of the broadest interpretation and equivalent arrangements.

What is claimed is:

1. A method of making a metal-electrodeposited insulator substrate, comprising:
forming a patterned conductive base layer on a pattern-forming surface of an insulator substrate, such that the patterned conductive base layer has a first continuous conductor part and a second continuous conductor part that is spaced apart from the first continuous conductor part, each of the first and second continuous conductor parts having an electroplating surface, the first continuous conductor part having a target portion and at least one sacrificial portion that extends from the target portion;
subjecting an assembly of the patterned conductive base layer and the insulator substrate to electroplating so as to simultaneously form first and second electroplating parts of a patterned electroplating layer on the patterned conductive base layer, such that the first electroplating part is formed on and overlaps entirely the electroplating surface of the first continuous conductor part, and that the second electroplating part is formed on and overlaps entirely the electroplating surface of the second continuous conductor part, the first electroplating part having at least one sacrificial portion that overlaps the sacrificial portion of the first continuous conductor part; and
removing the sacrificial portion of the first continuous conductor part and the sacrificial portion of the first electroplating part from the insulator substrate.

2. The method of claim 1, wherein an entire area of the electroplating surface of the first continuous conductor part and an entire area of the electroplating surface of the second continuous conductor part are substantially the same.

3. The method of claim 2, wherein the forming of the patterned conductive base layer on the pattern-forming surface includes forming an active metal-containing layer on the pattern-forming surface of the insulator substrate.

4. The method of claim 3, wherein the forming of the patterned conductive base layer on the pattern-forming surface further includes forming an electroless plating seed layer on the active metal-containing layer.

5. The method of claim 4, wherein the forming of the patterned conductive base layer on the pattern-forming surface further includes cutting through a stack of the active metal-containing layer and the electroless plating seed layer so as to form the stack into the first and second continuous conductor parts and an excess conductor part that is spaced apart from the first and second continuous conductor parts and that separates the first and second continuous conductor parts apart from each other.

6. The method of claim 5, wherein the cutting of the stack of the active metal-containing layer and the electroless plating seed layer is conducted by laser cutting.

7. The method of claim 5, wherein the pattern-forming surface has first and second roughened regions and first and second non-roughened regions, the second non-roughened region extending from the first roughened region, the first non-roughened region surrounding the first and second roughened regions and the second non-roughened region, the target portion of the first continuous conductor part being formed on and overlapping an entire area of the first roughened region of the pattern-forming surface, the sacrificial portion of the first continuous conductor part being formed on and overlapping an entire area of the second non-roughened region, the second continuous conductor part being formed on and overlapping an entire area of the second roughened region of the pattern-forming surface.

8. The method of claim 7, wherein at least one of the first and second roughened regions of the pattern-forming surface of the insulator substrate is roughened by laser ablation techniques.

9. The method of claim 7, further comprising removing the excess conductor part from the insulator substrate.

10. The method of claim 9, wherein the removing of the excessive conductor part from the insulator substrate is conducted prior to the formation of the patterned electroplating layer on the patterned conductive base layer.

11. The method of claim 1, wherein the insulator substrate is made from a polymeric resin material.

12. A metal-electrodeposited insulator substrate comprising:
an insulator substrate having a pattern-forming surface, said pattern-forming surface having first and second roughened regions and first and second non-roughened regions, said second non-roughened region extending from said first roughened region, said first non-roughened region surrounding said first and second roughened regions and said second non-roughened region and separating said first roughened region and said second non-roughened region apart from said second roughened region, each of said first and second roughened regions and said second non-roughened region having a peripheral edge, said pattern- forming surface being formed with first and second cut slits, said first cut slit surrounding and approximating said peripheral edges of said first roughened region and said second non-roughened region, said second cut slit surrounding and approximating said peripheral edge of said second roughened region, an entire area of said second roughened region being substantially equal to a total area of said first roughened region and said second non-roughened region;
a first multi-layer conductor stack formed on and overlapping an entire area of said first roughened region and surrounded by said first cut slit; and
a second multi-layer conductor stack formed on and overlapping an entire area of said second roughened region and surrounded by said second cut slit.

13. The metal-electrodeposited insulator substrate of claim 12, wherein each of said first and second multi-layer conductor stacks has a stack thickness, the stack thicknesses of said first and second multi-layer conductor stacks being substantially the same.

14. The metal-electrodeposited insulator substrate of claim 12, wherein said insulator substrate is made from a polymeric resin material.

15. The metal-electrodeposited insulator substrate of claim 12, wherein each of said first and second multi-layer conductor stacks includes an active metal-containing layer formed on said pattern-forming surface of said insulator substrate.

16. The metal-electrodeposited insulator substrate of claim 15, wherein each of said first and second multi-layer conductor stacks further includes an electroless plating seed layer formed on said active metal-containing layer.

17. The metal-electrodeposited insulator substrate of claim 16, wherein each of said first and second multi-layer conductor stacks further includes an electroplating layer formed on said electroless plating seed layer.
